(19) United States
(12) Patent Application Publication
(10) Pub. No.: US 2011/0180044 A1
(43) Pub. Date: Jul. 28, 2011

(54) METHOD AND DEVICE FOR CORRECTING A TEMPERATURE-DEPENDENT LENGTH CHANGE OF AN ACTUATOR UNIT DISPOSED IN THE HOUSING OF A FUEL INJECTOR

(76) Inventor: Jürgen Fritsch, Regensburg (DE)

(21) Appl. No.: 13/062,063

(22) PCT Filed: Aug. 19, 2009
(86) PCT No.: PCT/EP2009/060714

§ 371 Date: Apr. 14, 2011

(30) Foreign Application Priority Data
Sep. 4, 2008 (DE) 10 2008 045 955.0

(51) Int. Cl. F02D 41/14; G01R 27/00

(52) U.S. Cl. 123/478; 702/65

(57) ABSTRACT

A method and a device correct a temperature-dependent length change of an actuator unit (3) disposed in a housing (2) of a fuel injector (1). A known method of maintaining an idle stroke (L) formed between the actuator unit (3) and a control valve of the fuel injector involves compensating for a temperature-dependent length change by measuring the capacity of the actuator unit (3) and thereby determining the temperature (Ta). However, in the process an additional test impulse is used to trigger the actuator unit (3). Therefore, it is proposed to forego the use of a test impulse and to measure the capacity (CA-PA) directly at an active trigger impulse. The method is much more precise and reliable since the current operating parameters, such as fuel pressure, fuel temperature and actuation energy, among others, are taken into account.

### CROSS-REFERENCE TO RELATED APPLICATIONS

This application is a U.S. National Stage Application of International Application No. PCT/EP2009/060714 filed Aug. 19, 2009, which designates the United States of America, and claims priority to German Application No. 10 2008 045 955.0 filed Sep. 4, 2008, the contents of which are hereby incorporated by reference in their entirety.

### TECHNICAL FIELD

The invention relates to a method and to a device for compensating a temperature-induced change in length of an actuator unit arranged in the housing of a fuel injector.

### BACKGROUND

It is already known for a common-rail injection system having one or more fuel injectors, which inject the fuel directly into the cylinders of the internal combustion engine, to be used for diesel or gasoline engines. The fuel injector has an actuator unit which is arranged in a housing and which, when activated, actuates a valve unit. The central drive element of the actuator unit is a piezoelectric actuator which is actuated by at least one electrical activation pulse and which imparts a corresponding lift. A minimum idle stroke of for example 2 μm is formed between the actuator unit and the valve unit in order to ensure that the spray holes of the fuel injector are reliably sealed off in the rest state.

It is also known that the coefficient of thermal expansion of the actuator unit cannot be fully matched with that of its housing, and that temperature differences between the actuator unit and its housing can occur in particular in dynamic operation. This results, as a function of the temperature, in small differences in length between the actuator unit and the housing, which can lead to a change in the idle stroke. Since the length expansion of the actuator unit is relatively small in any case, at different operating temperatures, even the smallest changes in length of the actuator unit can have a massive impact on the injection behavior of the fuel injector since the idle stroke can unfavorably be correspondingly decreased or increased.

To solve said problem, it has hitherto been attempted to determine the dynamic behavior of the temperature of the actuator unit. From the temperature, it is then possible, from the known material constants or by empirical tests, to determine what influence the temperature has on the change in length of the actuator unit.

In DE 19931233 A1, it is proposed to determine the temperature of the actuating element (actuator unit) by means of a so-called small capacitance. The small capacitance is measured in an activation interval during which the fuel injector is not active. To measure the small capacitance, one or more test pulses are required by means of which the actuator unit is activated. Said method has the disadvantage that additional test pulses must be determined and applied in order to be able to measure the small capacitance. Furthermore, said method provides relatively imprecise results because present operating parameters, such as occur only during an active activation, cannot be measured.

In WO 2002092985, it is likewise proposed to take the capacitance of the actuator unit into consideration as a measure of the temperature. However, it is not possible to identify from said publication whether for example a temperature distribution is taken into consideration in the actuator unit. Furthermore, it is not possible to identify how the correction of the activation voltage is supposed to be configured in particular with regard to different operating states of the fuel injector.

In EP 1138935 B1, it is proposed, in the case of a piezoelectric actuator unit, to estimate the piezo temperature from the relationship between the charging energy and the energy recovered from the discharging process.

Furthermore, EP 1811164 B1 discloses a method in which the piezo temperature of a piezoelectric actuator unit is calculated on the basis of a model which accesses the fuel temperature at the pump inlet, the cooling water temperature, the rotational speed and the injection quantity.

### SUMMARY

According to various embodiments, a method and a device by means of which a temperature-induced change in length of the actuator unit is reliably compensated without significant expenditure by means of direct measurement of the capacitance during an active activation pulse.

According to an embodiment, in a method for compensating a temperature-induced change in length of an actuator unit arranged in a housing of a fuel injector, firstly the capacitance of the actuator unit being determined, the temperature of the actuator unit being determined from the capacitance, and a subsequent active activation pulse for the actuator unit being corrected taking into consideration the determined temperature, wherein the measurement of the present capacitance of the actuator unit is carried out during the operation of an internal combustion engine directly during at least one active activation pulse for the actuator unit.

According to a further embodiment, the capacitance of the actuator unit can be measured as a function of at least one operating parameter of the fuel injector. According to a further embodiment, the capacitance of the actuator unit can be determined as a function of the pressure, the temperature, the actuation energy, the activation duration, the fuel type and/or other influential factors. According to a further embodiment, the capacitance can be measured at the end of a charging process or during the holding phase of the active activation pulse. According to a further embodiment, the capacitance can be determined as a function of the thermal coupling between the actuator unit and its housing. According to a further embodiment, the temperature-induced change in length of the actuator unit can be corrected by changing the timing or by means of a changed actuation energy for the activation pulse. According to a further embodiment, to compensate the temperature-induced change in length of the actuator unit, a timing change can be converted into an equivalent change in the actuation energy, or vice versa. According to a further embodiment, the conversion values for the timing change or of the equivalent actuation energy can be stored in the form of a table, curve or as a formula.

According to another embodiment, a device for compensating a temperature-induced change in length of an actuator unit arranged in a housing of a fuel injector, for a method as mentioned above, may have a program-controlled processing unit, having a measuring device for the capacitance of the actuator unit, having a memory and having a program for compensating the temperature-induced change in length, wherein the program is formed with an algorithm by means of which the capacitance of the actuator unit can be measured during the operation of an internal combustion engine directly during at least one active activation pulse for the actuator unit.

According to a further embodiment of the device, the capacitance can be measured as a function of at least one operating parameter, for example the pressure, the actuation energy and/or the temperature. According to a further embodiment of the device, a table regarding the relationship between the capacitance and/or the actuator temperature as a function of the actuation energy and the pressure can be stored in the memory. According to a further embodiment of the device, a quantity characteristic map can be stored in the memory, by means of which quantity characteristic map, at any desired operating point of the fuel injector, a determined timing change is converted into an equivalent change of the actuation energy and vice versa. According to a further embodiment of the device, the program can be designed to compensate a temperature-induced change in length of the actuator unit by changing the timing for the activation pulse and/or by changing the actuation energy.

### BRIEF DESCRIPTION OF THE DRAWINGS

An exemplary embodiment is illustrated in the drawing and will be described in more detail in the following description.

FIG. 1 shows a schematic illustration of a detail of a longitudinal section through a fuel injector, illustrating in particular an actuator unit which is arranged in a housing and has a valve unit,

FIG. 2 shows a first diagram illustrating the relationship between the chamber temperature T_{K} and the temperature of the housing T_{G} of the drive unit,

FIG. 3 shows a second diagram illustrating the relationship between the capacitance (CAPA) of the actuator unit as a function of the pressure, the temperature and the actuation energy,

FIG. 4 shows a third diagram depicting the illustration of FIG. 3 in linearized form,

FIG. 5 shows a block circuit diagram for determining the capacitance of the actuator unit for a working point,

FIG. 6 shows a fourth diagram illustrating the relationship between the capacitance CAPA and the temperature Ta of the actuator unit,

FIG. 7 shows a block circuit diagram for calculating the correction for the activation pulse,

FIG. 8 shows an algorithm for determining the timing correction and correction of the actuation energy, and

FIG. 9 shows a block circuit diagram of a device according to various embodiments.

### DETAILED DESCRIPTION

The method and device according to various embodiments for compensating a temperature-induced change in length of an actuator unit and having the characterizing features as described above yield the advantage that the measurement of the present capacitance, and the present temperature determined therefrom and the temperature-induced change in length of the actuator unit, are determined directly during the operation of an internal combustion engine during an active activation pulse for the actuator unit. An additional test pulse is not required. Such a measurement process is significantly easier and more advantageous to implement. Furthermore, improved and more reliable measurement values and results are obtained because the attainable correction quality is for example not dependent on a distorted signal-noise ratio. It is also considered to be advantageous that, in the case of a multiple injection which has for example 5 or 6 activation pulses, the measurement may be carried out or repeated during any desired activation pulse.

The measures specified according to various embodiments yield advantageous refinements of and improvements to the general method and device as described above. It is considered to be particularly advantageous for the capacitance of the actuator unit to be measured as a function of at least one operating parameter of the fuel injector. In this way, real conditions can be replicated, such that the correction of the temperature-induced change in length can be carried out more effectively and precisely.

Another aspect of the various embodiments can also be seen in that the capacitance of the actuator unit is determined as a function of the pressure, the temperature, the actuation energy, the activation duration, the fuel type and/or other influential factors. This leads to a reliable correction of the temperature-induced change in length.

It has also proven to be advantageous for the capacitance of the actuator unit to be measured at the end of a charging process or during the holding phase of the active control pulse. The time for the desired capacitance measurement can be very easily determined during the active activation pulse, because the start and the profile of the activation pulse are predefined and therefore known. It is thus possible, for example, for the capacitance measurement to take place 180 μs after the start of the activation pulse.

According to another embodiment the capacitance can be determined as a function of the thermal coupling between the actuator unit and its housing.

For the correction according to various embodiments, it is provided that the temperature-induced change in length of the actuator unit is corrected by means of a simple change of the timing for the activation pulse. It is alternatively provided that the actuation energy for the activation pulse is adapted in order to obtain a corresponding change in temperature for the actuator unit.

According to another embodiment, the temperature-induced change in length of the actuator unit can selectively be converted by means of a timing change into an equivalent change in the actuation energy, or vice versa. The conversion is advantageously carried out by means of a table stored in a memory, a stored characteristic map, a curve or by means of a mathematical formula.

In modern motor vehicles, use is made of internal combustion engines, which are generally formed with a common-rail injection system for injecting fuel. In the common-rail injection system, use is made of one or more fuel injectors by means of which the fuel, for example diesel oil or gasoline, is injected at high pressure directly into the cylinders of the internal combustion engine.

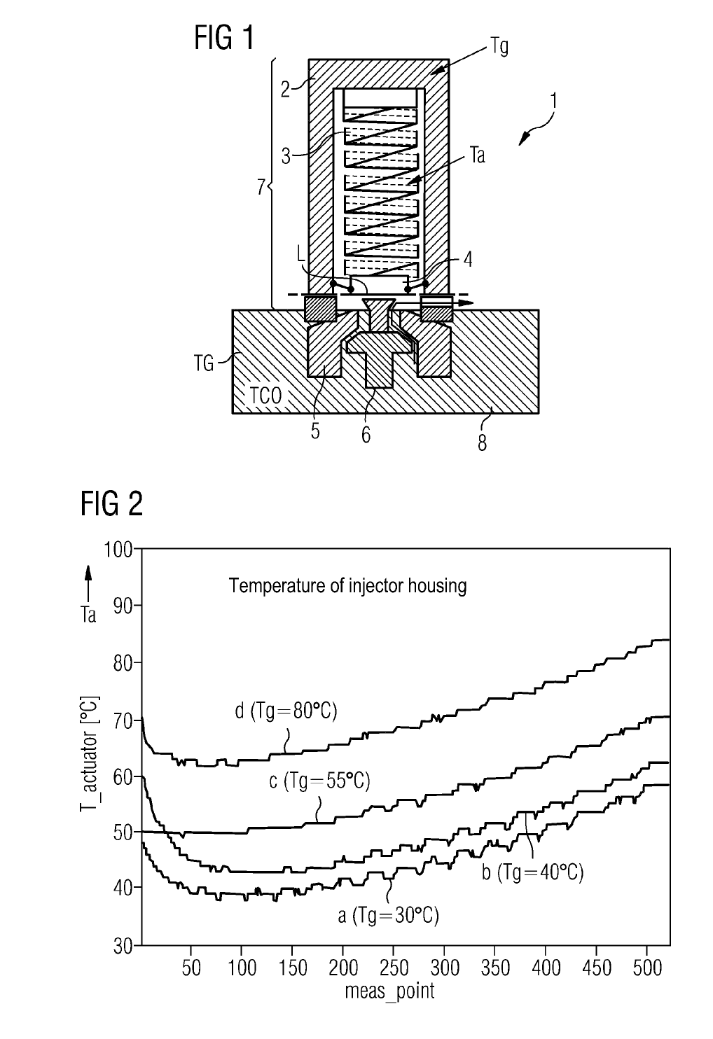

FIG. 1 shows a longitudinal section through a drive unit 7 according to various embodiments of the fuel injector 1 in a schematic illustration. As can also be seen from FIG. 1, the drive unit 7, designed preferably as a piezoelectric actuator unit 3, is arranged in a housing 2.

The actuator unit 3 is fixedly connected with its upper end to its housing 2. The lower end of the actuator unit 3 is closed off by a base plate 4 and is movable in the longitudinal direction. A valve body 8 with a mushroom-shaped valve 6 and with a valve piston 5 is arranged below the base plate 4. The mushroom-shaped valve 6 can be controlled by means of pressure on the valve piston 5. A minimum gap of for example L=2 μm is formed as an idle stroke between the base plate 4 and the valve piston 5. The idle stroke L is necessary in order to ensure that, in the non-activated state of the actuator unit 3, the spray holes at the lower end of the fuel injector 1 are reliably closed such that no fuel can emerge.

The actuator unit 3 is activated by means of at least one electrical activation pulse and, depending on its design, generates a change in length of approximately 30 to 50 μm. As a result of the change in length of the actuator unit 3, the base plate 4 presses against the valve piston 5 and opens the mushroom-shaped valve 6. The hydraulic switching mechanism thereby triggered finally has the result that spray holes, which are situated in the lower part of a valve body 8, for the discharge of fuel are opened.

In general, for an injection cycle, a plurality of injection pulses is used in order to optimally control the combustion of the fuel. For example, in the case of a diesel injection, 5 to activation pulses are activated, with one or two pilot injections being discharged before a main injection. After the main injection, an accumulated small injection may follow, and approximately 2 to 3 ms after the main injection, for a regeneration mode, a further 1 to 2 activation pulses are activated.

According to various embodiments, the capacitance of the actuator unit 3 is measured during at least one of the abovementioned activation pulses per cycle. In principle, the capacitance of the actuator unit may be measured during any desired activation pulse and the measurement may be repeated as often as desired. In a specific exemplary embodiment, the capacitance is measured during the charging process of an active activation pulse, for example at the end of the charging process after approximately 180 μs. Alternatively, the capacitance may also be measured during the subsequent holding phase of the active activation pulse. Since the time of the start of the charging process of an active activation pulse is known, the trigger (measurement start) for the measurement of the capacitance may be selected at any desired time, since the injection process is not influenced by the measurement. To determine the capacitance of the actuator unit, the voltage reached at the time of triggering is measured, and the charging current is integrated over the charging process up to the triggering point. The integration of the charging current over the time yields the entire charge that has flowed into the actuator unit 3. From the charge and the voltage, the present capacitance of the actuator unit 3 is determined by simple quotient formation.

A particular advantage of various embodiments is that the measurement of the present capacitance of the actuator unit 3 can be carried out during dynamic operation of the internal combustion engine at one or more active activation pulses. A test pulse for determining the capacitance is not required. A further advantage according to various embodiments also arises in that, by means of the direct measurement during an active activation pulse, the present operating parameters of the fuel injector 1 are automatically taken into consideration. In this way, the method according to various embodiments is particularly realistic and reliable because the influences of the actuation energy, of the pressure (rail pressure), of the temperature, of the fuel type and of other influential factors are explicitly taken into consideration in the determination of the capacitance.

FIG. 1 also shows measurement points for the temperature T_{G} of the drive unit 7 and for the temperature Ta of the actuator unit 3. On account of the direct contact between the upper part of the actuator unit 3 and its housing 2, the heat conduction is very good, and only small temperature differences are to be expected. The black arrow P in the region of the mushroom-shaped valve 6 and of the valve piston 5 symbolizes the leakage flow of the fuel.

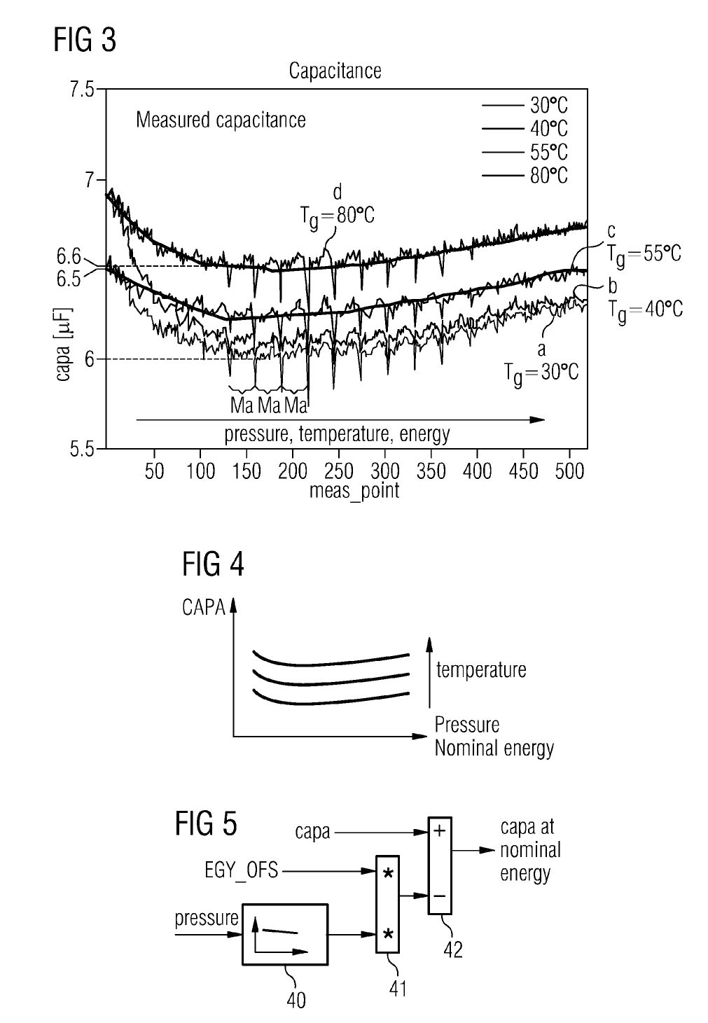

Below, the relationship between the temperature Ta of the actuator unit 3 and the temperature T_{G} of the housing 2 of the drive unit 7 will be explained in more detail on the basis of the diagrams of FIGS. 2 and 3.

A total of four temperature curves a,b,c,d are illustrated in the diagram of FIG. 2. The determined temperature T_{housing} of the housing 2 of the drive unit 7 is plotted on the Y axis. Measurement points in the range from 0 to 500 for the profile of the temperature T_{G} are plotted on the X axis. The illustrated curves a,b,c,d were determined by experimental measurements in a temperature chamber and represent the relationship between the temperature T_{G} of the housing 2 of the drive unit 7 and the chamber temperature T_{K} for the different measurement points. The test chamber was set to predefined constant chamber temperatures T_{K} for the individual measurement points. The lower curve a was measured at a chamber temperature T_{K}=30° C. For the curve b situated above, the chamber temperature was T_{K}=40° C.; for the next curve c, T_{K}=55° C., and for the uppermost curve d, T_{K}=80° C. For the measurement points, the pressure and the duration of the activation pulse were varied. FIG. 2 shows that the four temperatures a to d run, as a first approximation, approximately parallel.

FIG. 3 shows a further diagram in which the curves a to d illustrated in FIG. 2 are shown in a different form. As can be seen from FIG. 3, the capacitance CAPA [μF] of the actuator unit 3 was illustrated on the Y axis. The four curves a to d were likewise illustrated for chamber temperatures Tₖ of 30° C., 40° C., 55° C. and 80° C., as was described above with regard to FIG. 2. Plotted again on the X axis are measurement points between 0 and 500, wherein the pressure, the temperature and the actuation energy were varied in the same way, as in FIG. 2. Noticeable in these figures are sharp needles (spikes) which point downward.

A measurement section Ma lies in each case between two needle tips of a curve. Within in each case one measurement section Ma, the pressure in the system is held constant and the activation duration of the activation pulse is reduced. As can be seen from the diagram, the capacitance CAPA is approximately constant over a relatively long time. Said capacitance rises slightly at the end of the measurement section Ma and subsequently falls with a needle tip. The needle tips arise in that the activation duration of the activation pulse is reduced to such an extent that also the charging duration and therefore the energy of the activation pulse is reduced. In this way, a smaller overall amount of energy is supplied to the actuator unit.

What is crucial is that, when considering an individual curve, that is to say for a constant chamber temperature T_{K}, from left to right the pressure in the common rail system is constant for as long as no needle tip occurs, and the pressure is thereafter raised. At the same time, the measurement curve contains the information that the maximum charge which is applied to the actuator unit is dependent on the pressure. Overall, one is provided with the information as to what pressure measurement is carried out at and for what activation duration (timing) measurement is carried out and what charge energy has been applied to the actuator unit. It is therefore possible from said measurements to extract the capacitance CAPA substantially as a function of the pressure and the activation.

If the capacitance measurement takes place at different chamber temperatures, a change in the capacitance CAPA is obtained as a function of the temperature. For example, in the curve a (test chamber temperature T_{K}=30° C.), CAPA=6.0 μF is measured as the lowest capacitance. For curve d, with a test chamber temperature T_{K}=80° C., the lowest value obtained is in contrast a capacitance of approximately 6.6 μF. The curves b and c show corresponding intermediate values for the capacitance at test chamber temperatures of 40° C. and 50° C.

The solid lines in curves c, d show the determined average values for the capacitance CAPA.

Since the curves of FIG. 3 are relatively difficult to evaluate, FIG. 4 shows a third diagram illustrating the curves for the capacitance profile as trend curves. The capacitance CAPA of the actuator unit is plotted on the y axis and the pressure, or the nominal energy selected therefor (actuation energy), is plotted on the x axis. FIG. 4 therefore schematically shows the dependency of the capacitance CAPA of the actuator unit 3 on the temperature T_{G} of the housing of the drive unit 7 at a predefined pressure and corresponding actuation energy. It can also be seen from FIG. 4 that, for every pressure value in the system of the fuel injector, a certain nominal value for the actuation energy must be predefined. This means that, at a relatively high pressure in the system, a relatively high opening force must also be imparted. The relatively high opening force however requires a correspondingly relatively high nominal energy for actuating the injection valve. The pressure in the system therefore clearly defines the parameters with which the actuator unit 3 must be operated.

FIG. 5 shows a block circuit diagram for a device according to various embodiments by means of which the capacitance CAPA can be calculated from the influence of an energy offset (EGY_OF) as a disturbance parameter. The disturbance parameters, as are illustrated in the set of curves of FIG. 3 in particular in the form of the needle tips, can be eliminated by means of the device of FIG. 5, so as to yield the set of curves of FIG. 4 which have a smoothed profile. Disturbance parameters are dependent on the pressure and arise if the energy of the activation pulse is changed.

In a block 40 of FIG. 5, the measured pressure value, or alternatively the setpoint value, is input as an input variable. A pressure-dependent characteristic map is stored in the block 40. Said characteristic map contains a derivation for the change in the capacitance per unit energy. The derivation is pressure-dependent. A pressure-corrected value for the capacitance CAPA is provided at the output side. Connected downstream of the block 40 is a block 41 designed as a multiplier. An energy offset EGY_OFS is also input into the multiplier 41 as a disturbance parameter. From a gradient dT/dEnergy*EGY_OFS, one obtains a corrective value for the capacitance CAPA. The result from the multiplier 41 is supplied to an adder 42. Also supplied to the adder 42 is the capacitance CAPA afflicted with disturbance effects, as determined from the measured values of FIG. 3. At the output of the adder 42, one is provided with a capacitance CAPA corrected to a nominal energy, that is to say the corrected capacitance CAPA is isolated from disturbing energy influences, and the smoothed, pressure-dependent set of curves of FIG. 4 is obtained.

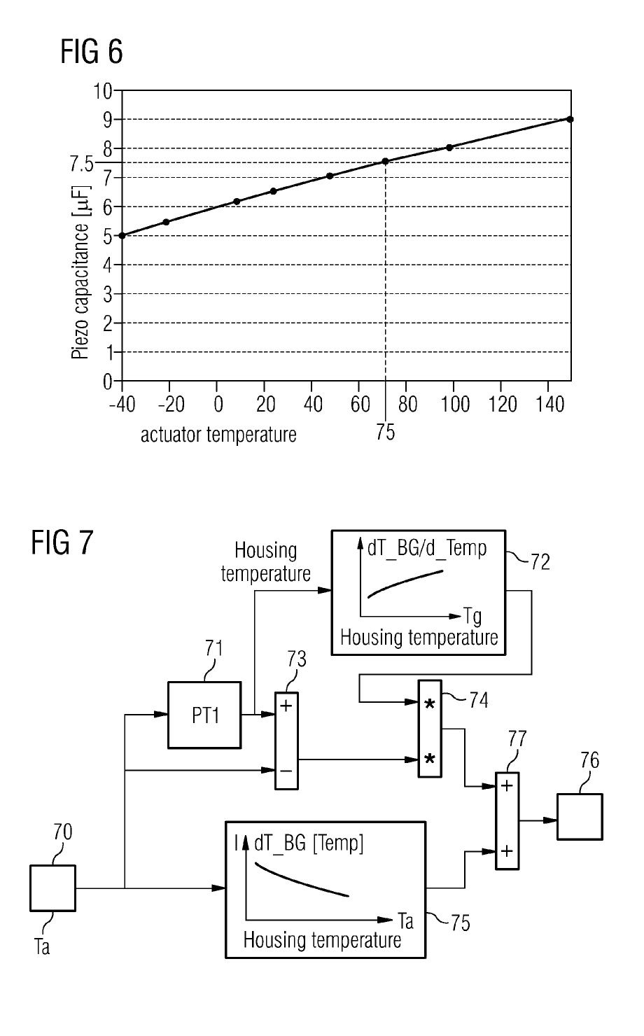

The measured capacitance value must furthermore be isolated from disturbing temperature influences. This takes place by means of the diagram of FIG. 6. In FIG. 6, the measured capacitance of the actuator unit 3 is plotted on the Y axis and the temperature Ta of the actuator unit 3 is plotted on the X axis. It is therefore possible, for every capacitance of the actuator unit, for the corresponding temperature Ta to be read out from the curve. For example, at a capacitance of 7.5 μF, the temperature of the actuator unit Ta=75° C., as can be seen from FIG. 6.

The diagram of FIG. 4 now incorporates the capacitance values cleansed of an energy offset and the temperature, said values thereby yielding the smoothed set of curves of FIG. 4. In FIG. 4, the capacitance CAPA (Y axis) is plotted against the pressure and the nominal energy (X axis). The curves therefore reflect, in corrected form, the temperature-dependent profile of the capacitance CAPA. The profile of the set of curves is slightly flatter than in FIG. 3. This is associated with the fact that the erroneous influence of the temperature has been eliminated.

The diagram of FIG. 4 is used conversely thereto, in that the pressure, the nominal energy and the capacitance value CAPA cleansed of disturbance variables are input as input variables, and the associated temperature Ta of the actuator unit 3 is read out of the characteristic map of FIG. 4. With the actuator temperature Ta obtained in this way, the temperature-induced change in length of the actuator unit 3 can be compensated either by correcting the energy or the timing for the activation pulse.

The above-described diagrams or the block circuit diagrams illustrate the algorithm according to various embodiments for compensating the temperature-induced change in length of the actuator unit 3. The algorithm is realized preferably in the form of a program which can be executed by a processor unit.

The block circuit diagram of FIG. 7 illustrates the entire relationship for realizing the temperature-induced change in length of the actuator unit 3, which has a corresponding effect on the size of the idle stroke with its set air gap L. Firstly, the temperature Ta determined from the measured capacitance of the actuator unit 3, as described above, is input at an input 70. A block 75 contains a diagram with a characteristic map by means of which the temperature Ta of the actuator unit 3 can be converted into a change of the idle stroke L. Therefore, the actuator temperature Ta is plotted on the X axis and the measure for the idle stroke L is plotted on the y axis. The illustrated curve dT_BG [Temp] (blind gap) therefore reflects the change in the idle stroke conditions as a function of the detected temperature Ta of the actuator unit 3.

As has already been illustrated in FIG. 1, the idle stroke L between the actuator unit 3 and the valve piston 5 is approximately 2 μm. In the event of a change in temperature of the actuator unit, therefore, the idle stroke L may be increased or decreased in size. In principle, on account of the selected material constants for the housing 2 and the actuator unit 3, the idle stroke L is approximately constant. However, if a temperature difference arises between the actuator unit 3 and the housing 2 during dynamic operation, this may lead to a reduction or increase of the idle stroke L. That is to say that, when the actuator unit 3 is activated, the injection valve opens later and closes earlier or vice versa. As a result, the predefined amount of fuel cannot be injected in the intended dosage. According to various embodiments, therefore, provision is made for the timing values for the activation pulse to be changed such that the intended fuel quantity can always be injected in a defined and reliable manner.

The upper part of FIG. 7 shows yet another corrective unit which comes into effect if a temperature difference arises between the actuator unit 3 and its housing 2, that is to say if imperfect temperature equalization between the actuator unit 3 and its housing 2 takes place. This occurs in particular if the temperatures are duly equal in a steady-state situation but the temperature Ta of the actuator unit 3 differs from the temperature T_{G} of its housing 2 in a dynamic situation. Therefore, the temperature Ta of the actuator unit 3 is also transmitted from the input 70 to a PT1 filter (block 71). The PT1 filter 71 constitutes a time delay for the temperature generation between the actuator unit 3 and its housing 2. According to said model, the housing temperature lags behind. The filtered and unfiltered temperature of the actuator unit 3 are supplied to an adder 73, such that as a result, the temperature difference between the actuator unit 3 and its housing 2 is provided at the outlet of the block 73.

Furthermore, the output signal of the PT1 block (block 71) is coupled to the diagram of a block 72. The diagram of the block contains a characteristic map reflecting the relationship between the relative change of the timing of the activation pulse and the temperature difference dT_BG/d_Temp (y axis). The temperature T_{G} of the housing of the drive unit 7 is plotted on the x axis. The characteristic map practically contains the temperature coefficients of the materials used for the housing of the drive unit 7. The result is multiplied, in the block 74, with the temperature difference, and is added, in an adder 77, to the output signal of the block 75. At an output 76, therefore, there is provided a corrective value for the timing of the activation signal, by means of which corrective value the idle stroke L is corrected as a function of the temperature-dependent change in length of the actuator unit 3.

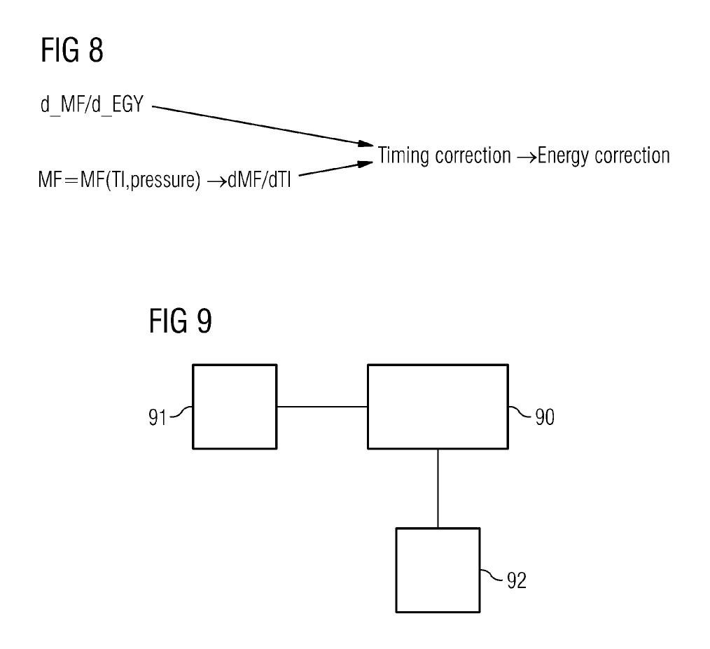

To clarify the compensation diagram, FIG. 8 indicates a formula by means of which the temperature-dependent change in length of the actuator unit 3 is corrected. The sensitivity to the energy adjustment for the activation pulse is stored for every operating point in a characteristic map. The fuel injector is for example operated at a pressure of 100 MP. The injection quantity during an injection pulse is for example 2 mg. At 100 MP, the actuator unit 3 is operated with a standard energy of 52 mJ. If the energy is increased for example by 10 mJ to 62 mJ, this results, for example, in a change in quantity of approximately 1.4 mg. In the event of a reduction of the energy, the injection quantity would be reduced by a certain amount.

The schematized formula of FIG. 8 shows the general approach on which various embodiments are based for the correction of the temperature-induced change in length of the actuator unit. In the schematic formula, the gradient of the change in quantity d_MF of the injected fuel over the change in energy d_EGY is extracted from the above-described diagram. The gradient is referred to as d_MF/d_EGY. Furthermore, the fuel quantity (MF) is a function of the timing (TI) for the activation pulse and the pressure in the fuel injector. From this, a change in quantity per unit change in timing d_MF/d_TI is determined according to the formula

MF=MF(TI,pressure)→d_{—}MF/d_TI.

The timing correction and/or the energy correction can be determined in conjunction with the gradient d_MF/d_EGY.

FIG. 9 shows a schematic illustration of a block circuit diagram of the device according to various embodiments. A processor unit 90 is connected to a measuring device 91 which is designed for measuring the capacitance of the actuator unit 3. Furthermore, the processor unit 90 is connected to a memory in which a program having an algorithm, data, curves, characteristic maps and measured values are stored. According to various embodiments, it is provided that the units 90 to 92 are for example already existing devices of an engine control unit.

What is claimed is:

1. A method for compensating a temperature-induced change in length of an actuator unit arranged in a housing of a fuel injector, the method comprising:
firstly, determining the capacitance of the actuator unit,
determining the temperature of the actuator unit from the capacitance, and
correcting a subsequent active activation pulse for the actuator unit taking into consideration the determined temperature,
wherein the measurement of the present capacitance of the actuator unit is carried out during the operation of an internal combustion engine directly during at least one active activation pulse for the actuator unit.

2. The method according to claim 1, wherein the capacitance of the actuator unit is measured as a function of at least one operating parameter of the fuel injector.

3. The method according to claim 1, wherein the capacitance of the actuator unit is determined as a function of at least one of: the pressure, the temperature, the actuation energy, the activation duration, the fuel type, and other influential factors.

4. The method according to claim 1, wherein the capacitance is measured at the end of a charging process or during the holding phase of the active activation pulse.

5. The method according to claim 1, wherein the capacitance is determined as a function of the thermal coupling between the actuator unit and its housing.

6. The method according to claim 1, wherein the temperature-induced change in length of the actuator unit is corrected by changing the timing or by means of a changed actuation energy for the activation pulse.

7. The method according to claim 6, wherein, to compensate the temperature-induced change in length of the actuator unit, a timing change is converted into an equivalent change in the actuation energy, or vice versa.

8. The method according to claim 6, wherein the conversion values for the timing change or of the equivalent actuation energy are stored in the form of a table, curve or as a formula.

9. A device for compensating a temperature-induced change in length of an actuator unit arranged in a housing of a fuel injector, comprising a program-controlled processing unit, having a measuring device for the capacitance of the actuator unit, having a memory and having a program for compensating the temperature-induced change in length, wherein
the program is formed with an algorithm by means of which the capacitance of the actuator unit can be measured during the operation of an internal combustion engine directly during at least one active activation pulse for the actuator unit.

10. The device according to claim 9, wherein the capacitance can be measured as a function of at least one operating parameter, for example the pressure, the actuation energy and/or the temperature.

11. The device according to claim 9, wherein a table regarding the relationship between at least one of the capacitance and the actuator temperature as a function of the actuation energy and the pressure is stored in the memory.

12. The device according to claim 9, wherein a quantity characteristic map is stored in the memory, by means of which quantity characteristic map, at any desired operating point of the fuel injector, a determined timing change is converted into an equivalent change of the actuation energy and vice versa.

13. The device according to claim 9, wherein the program is designed to compensate a temperature-induced change in length of the actuator unit by changing the timing for the activation pulse and/or by changing the actuation energy.

14. A fuel injector system for compensating a temperature-induced change in length of an actuator unit arranged in a housing of a fuel injector, comprising:
the fuel injector comprising an actuator unit;
a control unit operable:
firstly, to determine the capacitance of the actuator unit, wherein the measurement of the present capacitance of the actuator unit is carried out during the operation of an internal combustion engine directly during at least one active activation pulse for the actuator unit,
to determine the temperature of the actuator unit from the capacitance, and
to correct a subsequent active activation pulse for the actuator unit taking into consideration the determined temperature.

15. The fuel injector system according to claim 14, wherein the capacitance of the actuator unit is measured as a function of at least one operating parameter of the fuel injector.

16. The fuel injector system according to claim 14, wherein the capacitance of the actuator unit is determined as a function of at least one of: the pressure, the temperature, the actuation energy, the activation duration, the fuel type, and other influential factors.

17. The fuel injector system according to claim 14, wherein the capacitance is measured at the end of a charging process or during the holding phase of the active activation pulse.

18. The fuel injector system according to claim 14, wherein the capacitance is determined as a function of the thermal coupling between the actuator unit and its housing.

19. The fuel injector system according to claim 14, wherein the temperature-induced change in length of the actuator unit is corrected by changing the timing or by means of a changed actuation energy for the activation pulse.

20. The fuel injector system according to claim 19, wherein, to compensate the temperature-induced change in length of the actuator unit, a timing change is converted into an equivalent change in the actuation energy, or vice versa.

21. The fuel injector system according to claim 19, comprising a memory storing the conversion values for the timing change or of the equivalent actuation energy in the form of a table, curve or as a formula.
